(19) United States
(12) Patent Application Publication
(10) Pub. No.: US 2012/0127678 A1
(43) Pub. Date: May 24, 2012

(54) PORTABLE WIRELESS DEVICE

(75) Inventors: Nobuharu Mashima, Toyama (JP); Yasuhiro Nakamura, Ishikawa (JP); Yoshio Koyanagi, Kanagawa (JP); Noriyoshi Sato, Kanagawa (JP)

(73) Assignee: PANASONIC CORPORATION, Osaka (JP)

(21) Appl. No.: 13/388,427

(22) PCT Filed: Mar. 2, 2010
(86) PCT No.: PCT/JP2010/001425

§ 371 Date: Feb. 1, 2012

(30) Foreign Application Priority Data
Aug. 6, 2009 (JP) 2009-183495

(51) Int. Cl. H05K 7/02

(52) U.S. Cl. 361/753

(57) ABSTRACT

Provided is a portable wireless device which has a waterproofing effect and, at the same time, can improve resistance to static electricity. The portable wireless device (100) comprises a box-shaped housing (101) formed by fitting two cases at respective annular fitting surfaces of the two cases. In the portable wireless device (100), a circuit board (102) is provided in the housing (101). A waterproofing packing (103) has an annular shape and is provided between the fitting surfaces of the two cases and held by the two cases which constitute the housing (101). A conductor pattern (105) is integrally formed with the waterproofing packing (103) and is electrically connected to the circuit board (102).

### TECHNICAL FIELD

The present invention relates to a portable radio device especially having a waterproofing structure.

### BACKGROUND ART

It is important to secure resistance to static electricity from the outer side for an EMC countermeasure of electronic equipment. In particular, it is significantly difficult to secure resistance to static electricity in a mobile telephone because it is held by the hand, a circuit becomes integrated, and a gap between a case and a circuit is narrow due to miniaturization. In addition, problems such as a display-stop error may occur if the EMC countermeasure is not sufficient.

As EMC countermeasures of the related art, there are known three techniques as follows. As a first technique, the intrusion of static electricity from a gap is prevented by minimizing the gap caused at the time of fitting a casing. As a second technique, a countermeasure component for static electricity such as a varistor is used. As a third technique, a ground configuration of the circuit board is optimized in order to reliably dissipate the static electricity.

Under such circumstances, a waterproofing structure is widely employed as an essential structure of a mobile telephone. As a waterproofing structure for a mobile telephone, it is common to insert a waterproofing rubber packing to a gap between the casings (for example, Patent Literatures 1 and 2).

Specifically, in Patent Literature 1, the waterproofing structure is implemented by arranging a packing in the vicinity of the circuit board and interposing a cable for connecting an upper casing and a lower casing therebetween. In addition, an antenna is disposed in the inner side of the waterproof packing disclosed in Patent Literature 2.

### CITATION LIST

### Patent Literature

### PTL 1

Japanese Patent Application. Laid-open No. 2005-32752

### PTL 2

Japanese Patent Application Laid-open No. HEI 6-37876

### SUMMARY OF INVENTION

### Technical Problem

However, in Patent Literature 1, there is a problem that, although it has a waterproofing effect, a gap between casings is generated than before due to the addition of the packing, so that resistance to static electricity is reduced. In addition, in Patent Literature 2, although it has an effect for static electricity countermeasure when static electricity is intruded from the vicinity of antenna elements, it has no effect for the static electricity when the static electricity is intruded from portions except the vicinity of antenna elements.

It is therefore an object of the present invention to provide a portable radio device having a waterproofing effect and capable of improving resistance to static electricity at the same time.

### Solution to Problem

The portable radio device of the present invention has a casing that is box-shaped and formed by fitting two cases at a mating surface that is annular, employs a configuration having: a circuit board that is provided in the casing, a packing that is annular and is interposed between the first case and the second case on a mating surface between the first case and the second case forming the casing, and a conductive element that is integrated with the packing and electrically connected to the circuit board.

### Advantageous Effects of Invention

According to the present invention, it is possible to provide a portable radio device having a waterproofing effect and capable of improving resistance to static electricity at the same time.

### BRIEF DESCRIPTION OF DRAWINGS

FIG. 1 is a plan view illustrating a portable radio device according to Embodiment 1 of the present invention;

FIG. 2 is a plan view illustrating a portable radio device according to Embodiment 2 of the present invention; and

FIG. 3 is a plan view illustrating a portable radio device according to Embodiment 3 of the present invention.

### DESCRIPTION OF EMBODIMENTS

Hereinafter, embodiments of the present invention will be described in detail with reference to the accompanying drawings.

### Embodiment 1

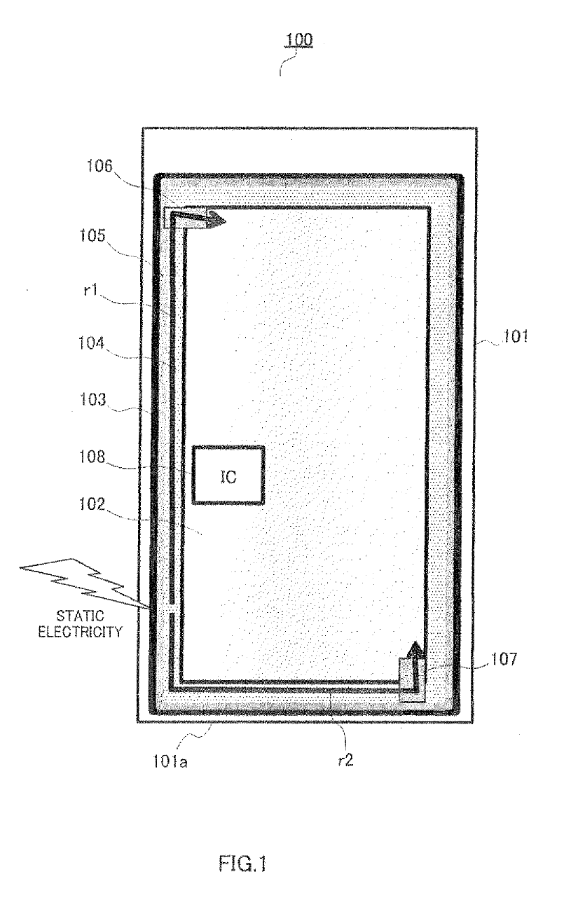

FIG. 1 is a plan view illustrating portable radio device 100 according to Embodiment 1 of the present invention.

Portable radio device 100 is mainly formed by casing 101, circuit board 102, waterproof packing 103, flexible printed circuit 104 (hereinafter, referred to as “FPC”), and IC 108. Hereinafter, each configuration will be described in detail.

Casing 101 has a box shape formed by fitting two cases at an annular mating surface. Casing 101 includes waterproof packing 103 arranged in the mating surface where two cases are fitted, and interposed between two cases. Moreover, casing 101 includes circuit board 102 and EPC 104.

Circuit board 102 is provided in casing 101. IC 108 is mounted on circuit board 102. Circuit board 102 is electrically connected to contact sections 106 and 107.

Waterproof packing 103 has an annular shape and is provided in the mating surface where two cases forming casing 101 are fitted. Waterproof packing 103 hermitically seats the gap between two cases formed when two cases are fitted by being interposed between two cases, Waterproof packing 103 is formed of a material having an elastic force that can reliably and hermitically seal the gap between two fitted cases. Waterproof packing 103 is formed integrally with FPC 104. In this case, waterproof packing 103 is formed integrally with FPC 104 by flowing and cooling a liquid rubber material into annular FPC 104.

Conductor pattern 105 is formed in FPC 104. FPC 104 has an annular shape and is formed integrally with waterproof packing 103.

Conductor pattern 105 is formed in FPC 104 and is arranged along outer peripheral section 101a of casing 101 and waterproof packing 103. Conductor pattern 105 is formed integrally with contact sections 106 and 107 and is electrically connected to ground section of circuit board 102 through contact sections 106 and 107.

Contact section 106 is formed integrally with conductor pattern 105 and is electrically connected to the ground section of circuit board 102 in the upper left corner of circuit board 102 in FIG. 1. Contact section 106 is electrically connected to the ground section of circuit board 102 at a location farthest from IC 108 of circuit board 102. Contact section 106 is electrically connected to the ground section of circuit board 102 by an elastic force of a spring structure or pressing of a protrusion (not illustrated) provided in casing 101 and the like.

Contact section 107 is formed integrally with conductor pattern 105 and is electrically connected to the ground section of circuit board 102 in the rower right corner of circuit board 102 in FIG. 1. Contact section 107 is electrically connected to the ground section of circuit board 102 at a location farthest from IC 108 of circuit board 102. Furthermore, contact section 107 is electrically connected to the ground section of circuit board 102 by an elastic force of a spring structure or pressing of a protrusion (not illustrated) provided in casing 101 and the like.

IC 108 constitutes the circuit section and is mounted on circuit board 102.

Hereinbefore, the configuration of portable radio device 100 has been described.

In portable radio device 100 having the configuration described above, static electricity intruding into the inner side of casing 101 from the outer side may dissipate to the ground section of circuit board 102 through contact section 106 and conductor pattern 105 of FPC 104 (path r1), and may dissipate to the ground section of circuit board 102 through contact section 107 and conductor pattern 105 of FPC 104 (path r2).

Thus, according to the present embodiment, it is possible to provide a waterproof effect and improve a static electricity resistance by electrically connecting the conductor pattern integrated with the waterproof packing to the ground section of the circuit board. According to the present embodiment, since the conductor pattern is electrically connected to the ground section of the circuit board using two contact sections, it is possible to reliably and electrically connect the conductor pattern and the ground section of the circuit board. According to the present embodiment, since the conductor pattern and the ground section of the circuit board are connected at a location farthest from the IC of the circuit board, it is possible to minimize negative influence on the IC when static electricity dissipates to the ground section of the circuit board. According to the present embodiment, since the waterproof packing and the FPC having the conductor pattern are formed integrally, it is possible to simplify a task for arranging the conductor pattern to the casing and reduce the manufacturing cost.

### Embodiment 2

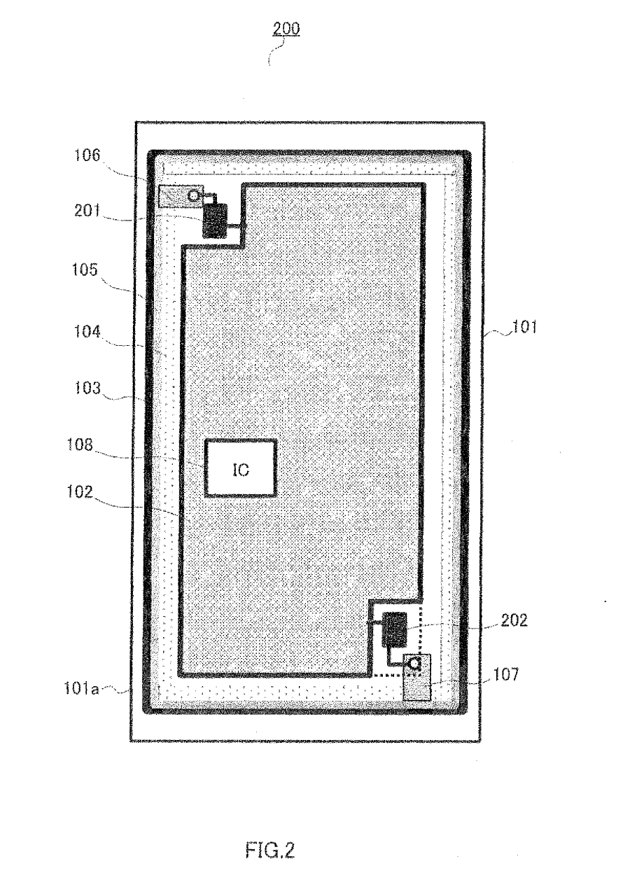

FIG. 2 is a plan view illustrating portable radio device 200 according to Embodiment 2 of the present invention.

In portable radio device 200 illustrated in FIG. 2, resistors 201 and 202 are added to portable radio device 100 according to Embodiment 1 illustrated in FIG. 1. In addition, in FIG. 2, the same components in FIG. 1 will be assigned the same reference numerals and overlapping explanation will be omitted.

Portable radio device 200 is mainly formed by casing 101, circuit board 102, waterproof packing 103, FPC 104, IC 108, and resistors 201 and 202. Hereinafter, the present embodiment will describe components different from the above Embodiment 1 in detail.

Casing 101 has a box shape formed by fitting two cases at an annular mating surface. Casing 101 includes waterproof packing 103 arranged in the mating surface where two cases are fitted, and interposed between two cases. Casing 101 includes circuit board 102, FPC 104, and resistors 201 and 202.

Circuit board 102 is provided in casing 101. IC 108 is mounted on circuit board 102, Circuit board 102 is electrically connected to resistors 201 and 202.

Conductor pattern 105 is formed in FPC 104 and is arranged along outer peripheral section 101a of casing 101 and waterproof packing 103. In addition, conductor pattern 105 is formed integrally with contact sections 106 and 107, is electrically connected to the ground section of circuit board 102 through contact section 106 and resistor 201, and is electrically connected to the ground section of circuit board 102 through contact section 107 and resistor 202.

Contact section 106 is formed integrally with conductor pattern 105 and is electrically connected to resistor 201 in the upper left corner of circuit board 102 of circuit board 102 in FIG. 1. Furthermore, contact section 106 is electrically connected to resistor 201 by an elastic force of a spring structure or pressing of a protrusion (not illustrated) provided in casing 101 and the like.

Contact section 107 is formed integrally with conductor pattern 105 and is electrically connected to resistor 202 in the lower right corner of circuit board 102 of circuit board 102 in FIG. 1. Furthermore, contact section 107 is electrically connected to resistor 202 by an elastic force of a spring structure or pressing of a protrusion (not illustrated) provided in casing 101 and the like.

Resistor 201 is connected in series between contact section 106 and circuit board 102 and electrically connects contact section 106 and the ground section of circuit board 102. Moreover, resistor 201 is electrically connected to the ground section of circuit board 102 at a location farthest from IC 108 of circuit board 102.

Resistor 202 is connected in series between contact section 107 and circuit board 102 and electrically connects contact section 107 and the ground section of circuit board 102. Resistor 202 is electrically connected to the ground section of circuit board 102 at a location farthest from IC 108 of circuit board 102.

Hereinbefore, the configuration of portable radio device 200 has been described.

In the portable radio device 200 having the configuration described above, static electricity intruding to the inner side of casing 101 from the outer side may dissipate to the ground section of circuit board 102 through conductor pattern 105 of FPC 104, contact section 106, and resistor 201, and may dissipate to the ground section of circuit board 102 through conductor pattern 105 of FPC 104, contact section 107, and resistor 202.

Thus, according to the present embodiment, in addition to the effect of the above Embodiment 1, it is possible to further improve resistance to static electricity by reducing energy of static electricity using a resistor.

### Embodiment 3

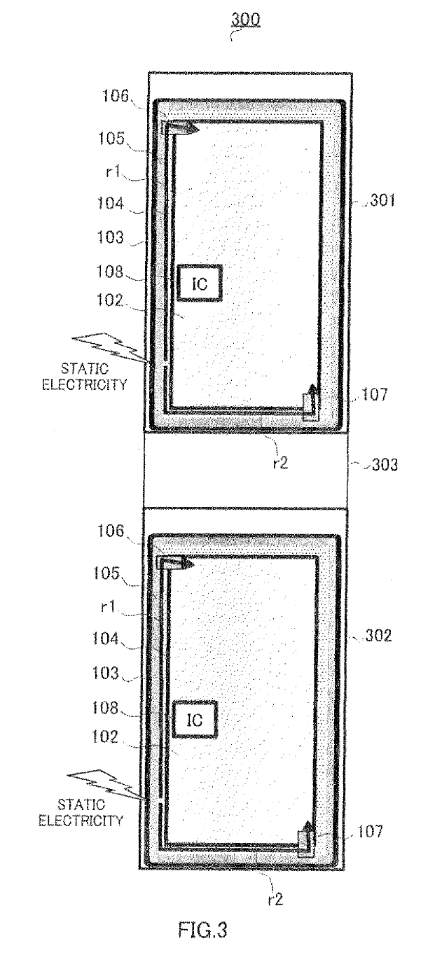

FIG. 3 is a plan view illustrating portable radio device 300 in an opened state according to Embodiment 3 of the present invention.

Portable radio device 300 illustrated in FIG. 3 includes casings 301 and 302 which have the same configuration as casing 101, instead of casing 101, and additionally includes hinge section 303 in comparison with portable radio device 100 illustrated in FIG. 1. In addition, in FIG. 3, the same components in FIG. 1 will be assigned the same reference numerals and overlapping explanation will be omitted.

Portable radio device 300 is mainly formed by first casing 301, second casing 302, and hinge section 303.

First casing 301 is foldably connected to second casing 302 through hinge section 303. Specifically, the state of first casing 301 changes from a closed state (not illustrated) in which first and second casings 301 and 302 are overlapped vertically to an opened state of FIG. 3 or from the opened state of FIG. 3 to the closed state.

Second casing 302 is foldably connected to first casing 301 through hinge section 303. Specifically, the state of second casing 302 changes from a closed state (not illustrated) in which first and second casings 301 and 302 are overlapped vertically to an opened state of FIG. 3 or from the opened state of FIG. 3 to the closed state.

Hinge section 303 connects first and second casings 301 and 302 in a rotatable manner.

In this manner, according to the present embodiment, in the portable radio device connected with rotatably connecting two casings, it is possible to obtain effects similar to those of Embodiment 1 described above.

In addition, according to the present embodiment, although the contact section of the conductor pattern and the ground section of the circuit board are connected directly, the present embodiment is not limited thereto and, similarly to Embodiment 2, the contact section of the conductor pattern and the ground section of the circuit board may be connected through a resistor.

In Embodiments 1 to 3 described above, although description has been made for the case where the structure of the portable radio device having a single casing or a folder type portable radio device, the present invention is not limited thereto and the present invention may be applied to any structure of the portable radio device such as a slide type. Although the IC is mounted on the circuit board in Embodiments 1 to 3 described above, the present invention is not limited thereto and any electronic component such as an LSI circuit other than the IC or the like may be mounted. Although the conductive element is electrically connected to the ground section of the circuit board using two contact sections in Embodiments 1 to 3 described above, the present invention is not limited thereto and the conductive element may be electrically connected to the ground section of the circuit board through any number of contact sections such as one or three or above. Although the waterproof packing is used in Embodiments 1 to 3 described above, the present invention is not limited thereto and any purpose packing with an excellent scaling property such as a dustproof packing other than the waterproof packing may be used.

The disclosures of Japanese Patent Application No 2009-183495 filed on Aug. 6, 2009, including the specification, drawings and abstract, is incorporated herein by reference in its entirety.

### INDUSTRIAL APPLICABILITY

The present invention is suitable especially for the portable radio device having a waterproofing structure.

1. A portable radio device that has a casing that is box-shaped and formed by fitting two cases at a mating surface that is annular, the portable radio device comprising:
a circuit board that is provided in the casing;
a packing that is annular and is interposed between a first case and a second case on the mating surface between the first case and the second case forming the casing; and
a conductive element that is integrated with the packing and electrically connected to the circuit board.

2. The portable radio device according to claim 1, further comprising a circuit section mounted on the circuit board, wherein the conductive element is electrically connected to the circuit board at a location farthest from the circuit section of the circuit board.

3. The portable radio device according to claim 1, wherein the conductive element is electrically connected to the circuit board through a resistor.

4. The portable radio device according to claim 1, a plurality of casings are provided movably to each other.
